(19) United States
(12) Patent Application Publication
(10) Pub. No.: US 2023/0290817 A1
(43) Pub. Date: Sep. 14, 2023

(54) SILICON CARBIDE SEMICONDUCTOR DEVICE

(71) Applicant: FUJI ELECTRIC CO., LTD., Kawasaki-shi (JP)

(72) Inventors: Syunki NARITA, Matsumoto-city (JP); Shinsuke HARADA, Tsukuba-shi (JP)

(73) Assignee: FUJI ELECTRIC CO., LTD., Kawasaki-shi (JP)

(21) Appl. No.: 18/174,830

(22) Filed: Feb. 27, 2023

(30) Foreign Application Priority Data
Mar. 11, 2022 (JP) 2022-038132

(51) Int. Cl. H01L 29/06; H01L 29/16; H01L 29/78

(52) U.S. Cl. CPC H01L 29/0634; H01L 29/1608; H01L 29/7811; H01L 29/7813

(57) ABSTRACT

A semiconductor device including a semiconductor substrate; a first parallel pn layer in which first first-conductivity-type column regions and first second-conductivity-type column regions repeatedly alternate with one another in an active region; a second parallel pn layer in which second first-conductivity-type column regions and second second-conductivity-type column regions repeatedly alternate with one another, in a termination region; a device structure provided between the first main surface of the semiconductor substrate and the first parallel pn layer; a first electrode provided at the first main surface and electrically connected to the device structure; and a second electrode provided at the second main surface of the semiconductor substrate. The plurality of second first-conductivity-type column regions and the plurality of second second-conductivity-type column regions are disposed in concentric shapes surrounding a perimeter of the first parallel pn layer in a plan view.

### CROSS REFERENCE TO RELATED APPLICATIONS

This application is based upon and claims the benefit of priority of the prior Japanese Patent Application No. 2022-038132, filed on Mar. 11, 2022, the entire contents of which are incorporated herein by reference.

### BACKGROUND OF THE INVENTION

### 1. Field of the Invention

Embodiments of the invention relate to a silicon carbide semiconductor device.

### 2. Description of the Related Art

Conventionally, a metal oxide semiconductor field effect transistor (MOSFET) that has insulated gates with a three-layer structure including a metal, an oxide film, and a semiconductor, as well as a superjunction (SJ) structure in which a drift layer is a parallel pn layer in which n-type regions and p-type regions are disposed adjacently and repeatedly alternate with one another in a first direction that is parallel to a main surface of a semiconductor substrate is commonly known.

The drift layer is a SJ structure, whereby compared to a normal drift layer configured by only an n⁻-type region, an impurity concentration of the drift layer can be increased and on-resistance is significantly reduced. Further, the drift layer is a SJ structure, whereby increases in on-resistance during high temperature operation are suppressed. High temperature operation is operation of a semiconductor device under a high-temperature environment or in a state in which the temperature of the semiconductor substrate (semiconductor chip) becomes high due to application of high voltage, conduction of large current, etc.

FIG. 11 is a plan view depicting a layout when a conventional silicon carbide semiconductor device is viewed from a front side of a semiconductor substrate thereof. In FIG. 11, the number of n-type column regions 131 and p-type column regions 132 is simplified and differs from that in FIG. 12. FIGS. 12, 13, and 14 are cross-sectional views depicting the structure along cutting line AA-AA′, cutting line BB-BB′, and cutting line CC-CC′ in FIG. 11, respectively. In FIGS. 11, 12, and 14, the p-type column regions 132 are indicated by hatching.

A conventional silicon carbide semiconductor device 150 depicted in FIGS. 11 to 14 is a trench-gate-type SiC-MOSFET with a SJ structure having, in a semiconductor substrate 140 that contains silicon carbide (SiC) as a semiconductor material, a parallel pn layer 103 that constitutes a drift layer. The semiconductor substrate 140 is formed by sequentially forming epitaxial layers 142, 143 by epitaxial growth on an n⁺-type starting substrate 141 that contains SiC as a semiconductor material; the epitaxial layers 142, 143 constitute a parallel pn layer 103 and a p-type base region 104, respectively.

In the parallel pn layer 103, the n-type regions (hereinafter, n-type column regions) 131 and the p-type regions (hereinafter, p-type column regions) 132 are disposed adjacently and repeatedly alternate with one another in a first direction X that is parallel to a main surface of the semiconductor substrate 140. The n-type column regions 131 and the p-type column regions 132, in an entire area of the semiconductor substrate 140, extend in a striped pattern in a second direction Y that is parallel to the main surface of the semiconductor substrate 140 and orthogonal to the first direction X.

In an active region 110 and an edge termination region 120, the drift layer is configured by the same SJ structure. The n-type column regions 131 and the p-type column regions 132 have substantially the same widths (widths in lateral direction) Wn101, Wp101 and substantially the same impurity concentrations. Substantially the same widths and substantially the same impurity concentration mean, respectively, the same widths and the same impurity concentrations within a range that includes an allowable error due to process variation.

In the active region 110 and the edge termination region 120, charge is generally in equilibrium between any one of the n-type column regions 131 and an adjacent one of the p-type column regions 132. Charge balance is an index that indicates a degree of equilibrium between an amount of charge expressed by a product obtained by multiplying a carrier concentration (impurity concentration) of the n-type column regions 131 and the width Wn101 thereof and an amount of charge expressed by a product obtained by multiplying a carrier concentration of the p-type column regions 132 and the width Wp101 thereof.

In the edge termination region 120, a voltage withstanding structure is disposed between the front surface of the semiconductor substrate 140 and the parallel pn layer 103. In the SiC-MOSFET, as the voltage withstanding structure, use of a double-zone junction termination extension (JTE) structure 121 that is configured by two p-type regions (p⁻-type region 122, p⁻⁻-type region 123) of differing impurity concentrations is commonly known.

The double-zone JTE structure 121 is disposed in concentric shapes that surround a periphery of the active region 110. Thus, the double-zone JTE structure 121 has, with respect to the n-type column regions 131 and the p-type column regions 132 that extend in a striped pattern in the second direction Y, portions that are orthogonal thereto and portions that are parallel thereto. In FIG. 11, an inner end (inner end of the p⁻-type region 122) and an outer end (outer end of the p⁻⁻-type region 123) of the double-zone JTE structure 121 are indicated by dashed lines.

The parallel pn layer 103 is provided closer to a chip end than is the double-zone JTE structure 121. An outermost column region of the parallel pn layer 103 in the first direction X is one of the p-type column regions 132. A portion between the semiconductor substrate 140 and the parallel pn layer 103 is a normal n-type drift region 135 that is not a SJ structure. The normal n-type drift region 135 is provided along an outer periphery of the semiconductor substrate 140 and surrounds a periphery of the parallel pn layer 103.

Reference numerals 101, 102, 105, 106, 107, 108, 109, 114, 113, 114, 115, 116, and 125 are, respectively, an n⁺-type drain region, an n-type buffer region, n⁺-type source regions, p⁺⁺-type contact regions, gate trenches, gate insulating films, gate electrodes, an interlayer insulating film, a source electrode, a drain electrode, and an n⁺-type channel stopper region. Reference numerals 111 and 112 are each p⁺-type regions for mitigating electric field applied to the gate insulating films 108 at bottoms of the gate trenches 107.

As for a conventional vertical silicon carbide semiconductor device with a SJ structure, a device has been proposed in which on a front surface of a semiconductor substrate, in a p-type RESURF layer formed straddling multiple p-type column regions that extend in parallel in a striped pattern, p⁺-type high-concentration regions are disposed so as to face the p-type column regions in a depth direction, whereby balance of potential in the p-type column regions of the edge termination region is uniformly maintained during avalanche breakdown and a breakdown voltage is ensured (for example, refer to International Publication No. WO 2017/212773).

As for another conventional vertical silicon carbide semiconductor device having a SJ structure, a device has been proposed in which, as a voltage withstanding structure and straddling multiple p-type column regions that extend in a striped pattern parallel to a front surface of a semiconductor substrate, multiple p-type regions of a same impurity concentration are disposed apart from one another in concentric shapes surrounding a periphery of an active region and in a direction of a normal vector, protrude beyond p-type column regions, whereby local concentration of electric field in an edge termination region is suppressed and breakdown voltage is enhanced (for example, refer to International Publication No. WO 2017/183375).

As for another conventional vertical silicon carbide semiconductor device having a SJ structure, a device has been proposed in which, a portion of overlap between p-type column regions that extend in a striped pattern parallel to a front surface of a semiconductor substrate, and a p-type RESURF layer that surrounds a periphery of the active region between the front surface of the semiconductor substrate and the SJ structure is reduced and depletion conditions during an off-state are obtained for key portions of the edge termination region, whereby a breakdown voltage margin of the edge termination region is ensured (for example, refer to Japanese Laid-Open Patent Publication No. 2010-040973).

### SUMMARY OF THE INVENTION

According to an embodiment of the invention, a silicon carbide semiconductor device includes: a semiconductor substrate that contains silicon carbide and has a first main surface and a second main surface opposite to each other, the semiconductor substrate having an active region and a termination region surrounding a periphery of the active region in a plan view of the semiconductor device; a first parallel pn layer in which a plurality of first first-conductivity-type column regions, each being of a first conductivity type, and a plurality of first second-conductivity-type column regions, each being of a second conductivity type, are disposed adjacently and repeatedly alternate with one another, the first parallel pn layer being provided in the semiconductor substrate, in the active region; a second parallel pn layer in which a plurality of second first-conductivity-type column regions and a plurality of second second-conductivity-type column regions are disposed adjacently and repeatedly alternate with one another, the second parallel pn layer being provided in the semiconductor substrate, in the termination region, the second parallel pn layer being in contact with the first parallel pn layer; a device structure provided in the semiconductor substrate, between the first main surface of the semiconductor substrate and the first parallel pn layer; a first electrode provided at the first main surface and electrically connected to the device structure; and a second electrode provided at the second main surface of the semiconductor substrate. The plurality of second first-conductivity-type column regions and the plurality of second second-conductivity-type column regions are disposed in concentric shapes surrounding a perimeter of the first parallel pn layer in the plan view of the semiconductor device.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a silicon carbide semiconductor device according to a first embodiment is viewed from a front side of a semiconductor substrate thereof.

FIG. 2 is a cross-sectional view depicting the structure along cutting line A-A′ in FIG. 1.

FIG. 3 is a cross-sectional view depicting the structure along cutting line B-B′ in FIG. 1.

FIG. 4 is a cross-sectional view depicting the structure along cutting line C-C′ in FIG. 1.

FIG. 5A is a diagram for describing a mechanism of electric field concentration at a double-zone JTE structure.

FIG. 5B is a diagram for describing a mechanism of electric field concentration at the double-zone JTE structure.

FIG. 6A is a diagram for describing a positional relationship between p-type column regions of an edge termination region and a double-zone JTE structure of the first embodiment.

FIG. 6B is a diagram for describing the positional relationship between the p-type column regions of the edge termination region and the double-zone JTE structure of the first embodiment.

FIG. 6C is a diagram for describing the positional relationship between the p-type column regions of the edge termination region and the double-zone JTE structure of the first embodiment.

FIG. 7 is a plan view depicting a layout when a silicon carbide semiconductor device according to a second embodiment is viewed from a front side of a semiconductor substrate thereof.

FIG. 8 is a cross-sectional view depicting the structure along cutting line D-D′ in FIG. 7.

FIG. 9A is a cross-sectional view of a structure of a silicon carbide semiconductor device according to a third embodiment.

FIG. 9B is a characteristics diagram depicting a relationship between breakdown voltage and charge balance in a direction of a normal vector, in a second parallel pn layer in FIG. 9A.

FIG. 10 is a cross-sectional view depicting a structure of a silicon carbide semiconductor device according to a fourth embodiment.

FIG. 11 is a plan view depicting a layout when a conventional silicon carbide semiconductor device is viewed from a front side of a semiconductor substrate thereof.

FIG. 12 is a cross-sectional view depicting the structure along cutting line AA-AA′ in FIG. 11.

FIG. 13 is a cross-sectional view depicting the structure along cutting line BB-BB′ in FIG. 11.

FIG. 14 is a cross-sectional view depicting the structure along cutting line CC-CC′ in FIG. 11.

### DETAILED DESCRIPTION OF THE INVENTION

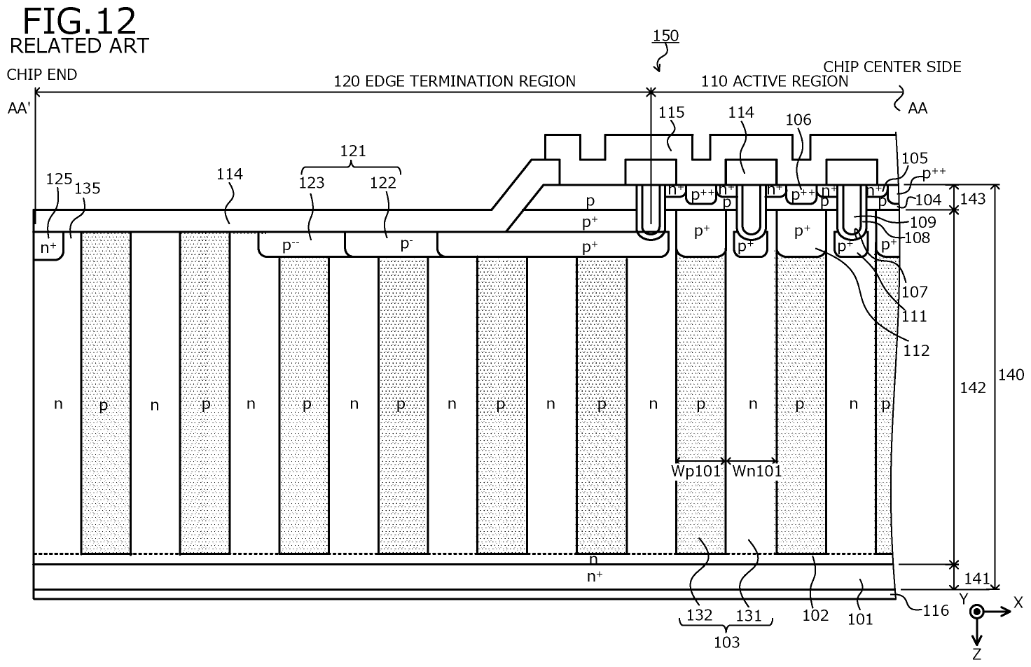

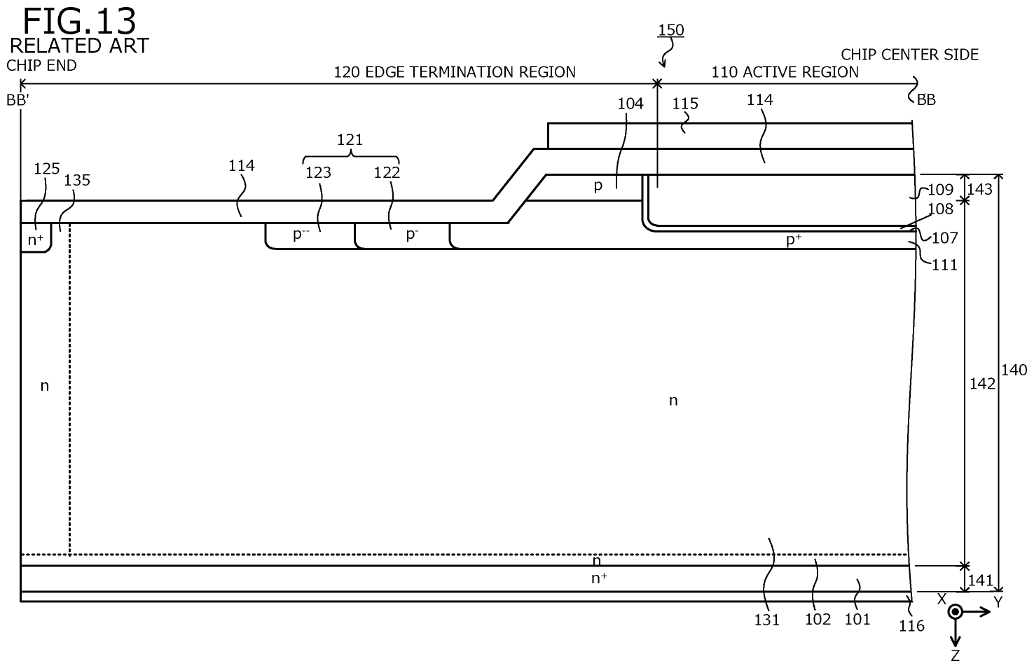

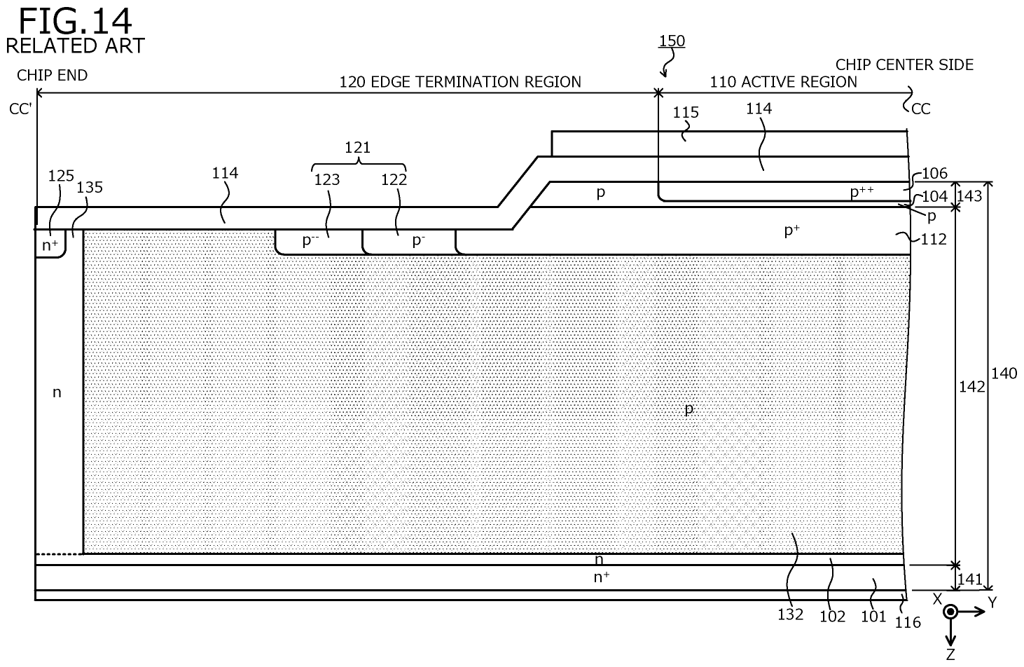

First, problems associated with the conventional techniques are discussed. As described above, in the conventional SiC-MOSFET with a SJ structure (refer to FIGS. 11 to 14), the drift layer is configured by the same the SJ structure (the n-type column regions 131 and the p-type column regions 132) in the active region 110 and the edge termination region 120. Thus, the breakdown voltage of the edge termination region 120 is lower than the breakdown voltage of the active region 110 and avalanche breakdown easily occurs in the edge termination region 120. As a result, a problem arises in that resistance to destruction is small as compared to an instance of avalanche breakdown in the active region 110, which has a large area and occupies a majority of the area (surface area) of the semiconductor substrate 140.

Embodiments of a silicon carbide semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

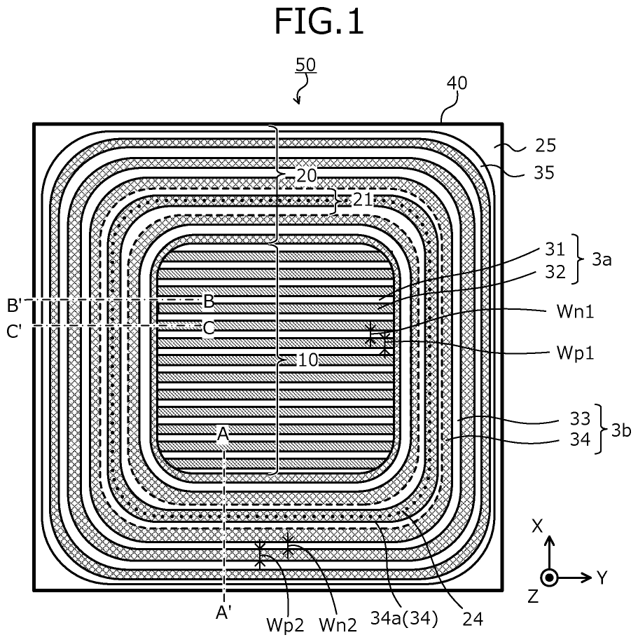

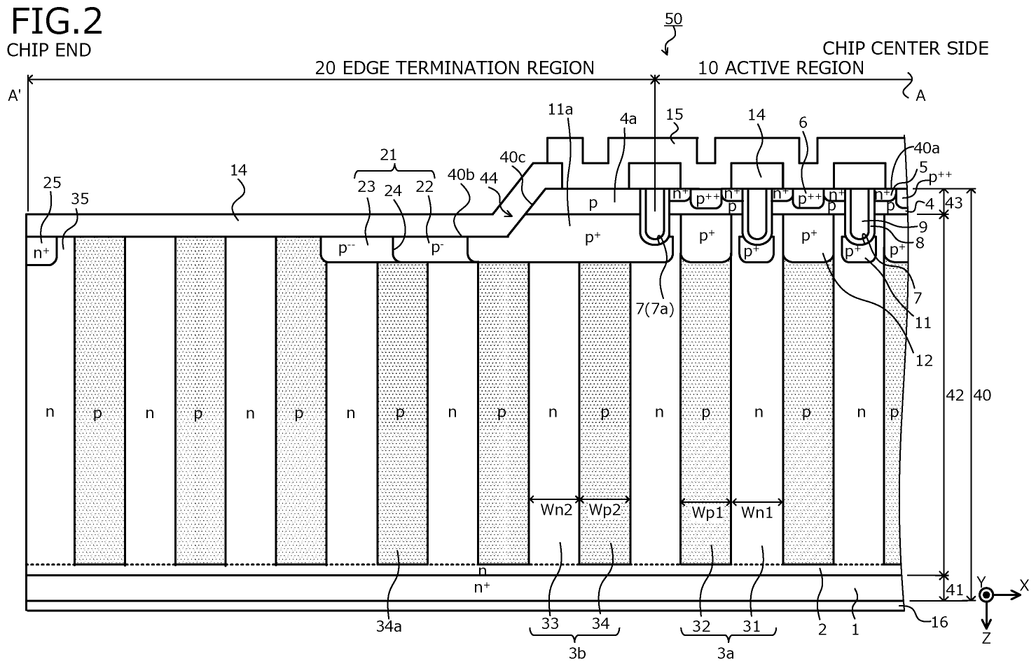

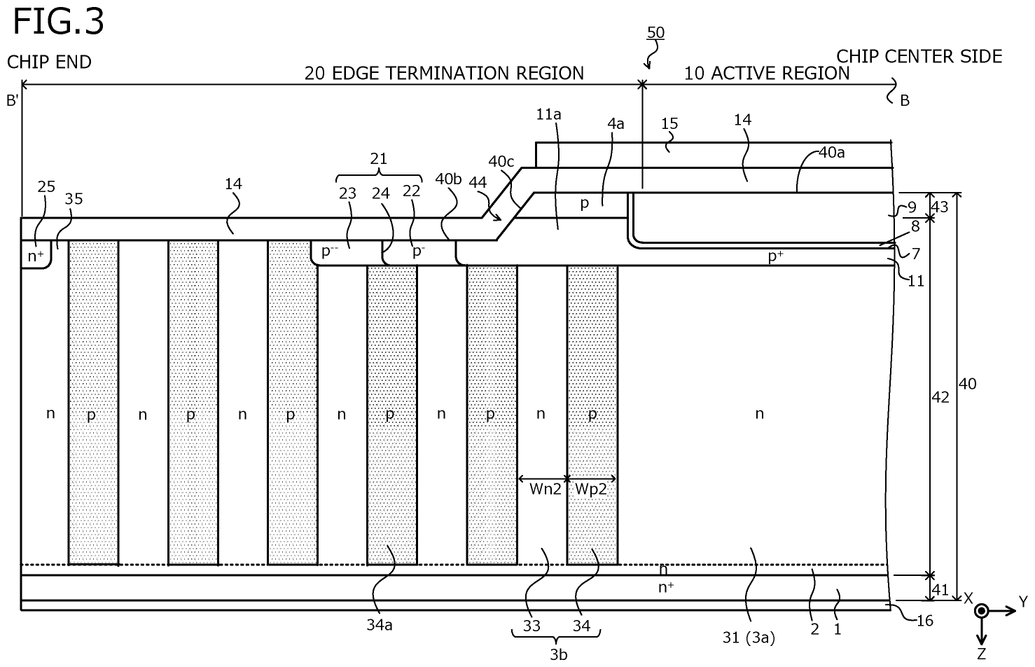

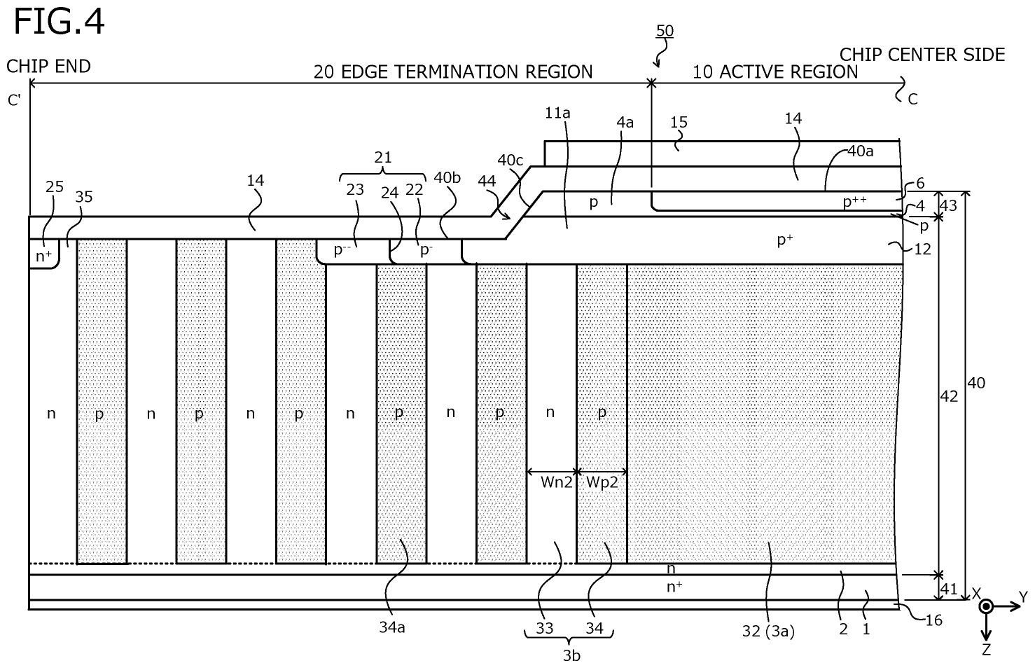

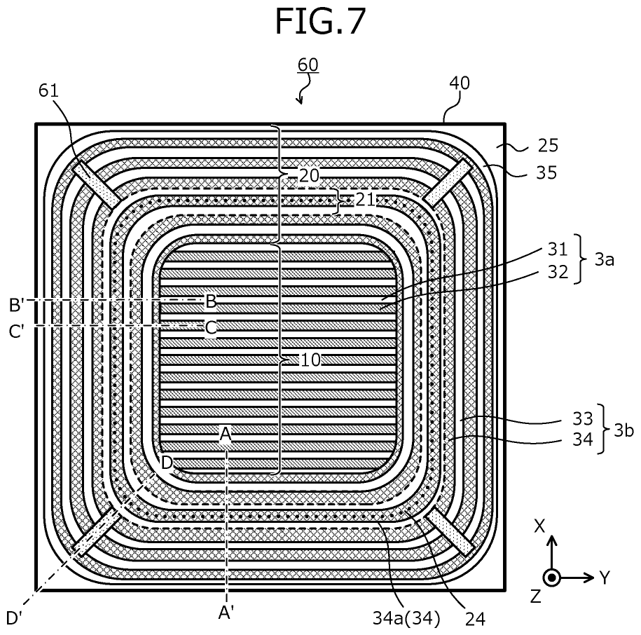

A structure of a silicon carbide semiconductor device according to a first embodiment is described. FIG. 1 is a plan view depicting a layout when the silicon carbide semiconductor device according to the first embodiment is viewed from a front side of a semiconductor substrate thereof. FIGS. 2, 3, and 4 are cross-sectional views depicting the structure along cutting line A-A′, cutting line B-B′, and cutting line C-C′ in FIG. 1, respectively. In FIGS. 2 to 4, the number of n-type column regions 31, 33 and the p-type column regions 32, 34 is simplified and differs from that in FIG. 1. In FIGS. 1 to 4, the p-type column regions 32, 34 are indicated by hatching (similarly in FIGS. 7, 8, 9A, and 10). In FIG. 1, to clearly depict an arrangement of the p-type column regions 32, 34 in a plan view, the p-type column regions 32 and the p-type column regions 34 are indicated by different hatching (similarly in FIG. 7).

A silicon carbide semiconductor device 50 according to the first embodiment depicted in FIGS. 1 to 4 has, in the active region 10, a general trench gate structure (device structure) at a front surface (first main surface) of a semiconductor substrate (semiconductor chip) 40 containing silicon carbide (SiC), and is a vertical SiC-MOSFET having a SJ structure in which first and second parallel pn layers 3a, 3b constitute a drift layer (drift region) of the active region 10 and an edge termination region 20, respectively. The trench gate structure is disposed in the active region 10, between a front surface of the semiconductor substrate 40 and the first parallel pn layer 3a.

The active region 10 is a region through which a main current flows when the MOSFET is in the on-state and is disposed in substantially a center (chip center) of the semiconductor substrate 40. In the active region 10, multiple unit cells (constituent units of a device) each having the same the trench gate structure are disposed adjacent to one another. The active region 10 is a region disposed in a chip center and, in the first direction X, extends to a center of an outermost (closest to a chip end) one (7a) of gate trenches 7 (refer to FIG. 2) and in the second direction Y, extends to non-depicted ends of n⁺-type source regions 5 (refer to FIG. 2).

The edge termination region 20 is a region between the active region 10 and an end (chip end) of the semiconductor substrate 40 and surrounds a periphery of the active region 10. The edge termination region 20 has a function of mitigating electric field of the drift layer near the front surface of the semiconductor substrate 40 and sustaining a breakdown voltage. The breakdown voltage is a voltage limit at which leakage current does not excessively increase and no malfunction or destruction of the device occurs. In the edge termination region 20, a double-zone junction termination extension (JTE) structure 21 is disposed between the front surface of the semiconductor substrate 40 and a second parallel pn layer 3b, as a voltage withstanding structure (refer to FIGS. 2 to 4).

The double-zone JTE structure 21 is a JTE structure in which two p-type regions (later-described p⁻-type region 22 and p⁻⁻-type region 23, refer to FIGS. 2 to 4) of differing impurity concentrations are disposed in descending order of impurity concentration in a direction from the active region 10 to the chip end, in adjacent concentric shapes surrounding the periphery of the active region 10. In FIG. 1, an inner end (inner end of the p⁻-type region 22) and an outer end (outer end of the p⁻⁻-type region 23) of the double-zone JTE structure 21 are indicated by a coarse dashed line and a border 24 between the p⁻-type region 22 and a p⁻⁻-type region 23 is indicated by a fine dashed line.

The p⁻-type region (first second-conductivity-type region) 22 and the p⁻-type region (second second-conductivity-type region) 23 of the double-zone JTE structure 21 are in contact with at least one of the later-described n-type column regions 33 and the later-described p-type column regions 34 of the second parallel pn layer 3b. The double-zone JTE structure 21 may be omitted. In an instance in which the double-zone JTE structure 21 is omitted, the second parallel pn layer 3b reaches the front surface of the semiconductor substrate 40 and is exposed at a portion (later-described second portion 40b) of the front surface of the semiconductor substrate 40, between a later-described the p⁺-type extension portion 11a and a later-described n⁺-type channel stopper region 25.

A layout of the SJ structure of the drift layer when viewed from the front side of the semiconductor substrate 40 differs in the active region 10 and the edge termination region 20. The drift layer in the active region 10 is the SJ structure configured by the first parallel pn layer 3a. The first parallel pn layer 3a is formed by n-type regions (hereinafter, n-type column regions (first first-conductivity-type column regions) 31 and p-type regions (hereinafter, p-type column regions (first second-conductivity-type column regions)) 32 that are disposed adjacently and repeatedly alternate with one another in the first direction X, which is parallel to a main surface of the semiconductor substrate 40.

The n-type column regions 31 and the p-type column regions 32 of the first parallel pn layer 3a, in substantially an entire area of the active region 10, extend in a striped pattern in the second direction Y, which is parallel to the main surface of the semiconductor substrate 40 and orthogonal to the first direction X. Equilibrium between charge of one of the n-type column regions 31 and charge of an adjacent one of the p-type column regions 32 is generally maintained. Charge balance is an index indicating a degree of equilibrium between an amount of charge expressed as a product obtained by multiplying carrier concentration and a width of the n-type column regions, and an amount of charge expressed by a product obtained by multiplying carrier concentration and a width of the p-type column regions.

For example, a width Wn1 of each of the n-type column regions 31 in a lateral direction (the first direction X) thereof and a width Wp1 of the p-type column regions 32 in a lateral direction thereof are substantially equal and uniform in an entire area of the active region 10. An impurity concentration of the n-type column regions 31 and an impurity concentration of the p-type column regions 32 are substantially equal and uniform in the entire area of the active region 10. Substantially equal widths and substantially equal impurity concentrations means, respectively, equal widths and equal impurity concentrations within a range that includes an allowable error due to process variation.

The drift layer in the edge termination region 20 is a SJ structure configured by the second parallel pn layer 3b. The second parallel pn layer 3b is in contact with the first parallel pn layer 3a and surrounds a periphery of the first parallel pn layer 3a. The second parallel pn layer 3b is formed by n-type regions (n-type column regions (second first-conductivity-type column regions)) 33 and p-type regions (p-type column regions (second second-conductivity-type column regions)) 34 that are disposed adjacently and repeatedly alternate with one another in adjacent concentric shapes surrounding the periphery of the active region 10. Equilibrium between charge of one of the n-type column regions 33 and charge of an adjacent one of the p-type column regions 34 is generally maintained.

For example, a width Wn2 of each of the n-type column regions 33 in a lateral direction thereof and a width Wp2 of each of the p-type column regions 34 in a lateral direction thereof are substantially equal and uniform in an entire area of the edge termination region 20. The width Wn2 of the n-type column regions 33 in the lateral direction thereof may be substantially equal to the width Wn1 of the n-type column regions 31 in the lateral direction thereof, and the width Wp2 of the p-type column regions 34 in the lateral direction thereof may be substantially equal to the width Wp1 of the p-type column regions 32 in the lateral direction thereof. An impurity concentration of the n-type column regions 33 and an impurity concentration of the p-type column regions 34 are substantially equal and uniform in the entire area of the edge termination region 20.

An innermost column region of the second parallel pn layer 3b may be one of the n-type column regions 33 or may be one of the p-type column regions 34. In an instance in which the innermost column region of the second parallel pn layer 3b is one of the n-type column regions 33, an outermost column region of the first parallel pn layer 3a in the first direction X is one of the p-type column regions 32 (not depicted). In an instance in which the innermost column region of the second parallel pn layer 3b is one of the p-type column regions 34, the outermost column region of the first parallel pn layer 3a in the first direction X is one of the n-type column regions 31 (refer to FIGS. 1 to 4).

The innermost column region of the second parallel pn layer 3b, in the first direction X, is adjacent to and forms a pn junction with the outermost column region of the first parallel pn layer 3a in the first direction X. Equilibrium between charge of the outermost column region of the first parallel pn layer 3a in the first direction X and charge of the innermost column region of the second parallel pn layer 3b is generally maintained. The innermost column region of the second parallel pn layer 3b, in the second direction Y, is in contact with ends of all the n-type column regions 31 and ends of all the p-type column regions 32.

For example, in the conventional structure (refer to FIGS. 11 to 14), the n-type column regions 131 and the p-type column regions 132 in the edge termination region 120 extend in a striped pattern, whereby the edge termination region 120 has a structure that partially differs concentrically at substantially a same distance from the outer periphery of the active region 110 in the direction of the normal vector from the chip center to the chip end. Thus, when the MOSFET is off, electric field applied to the edge termination region 120 is not distributed evenly according to the distance from the outer periphery of the active region 110 in the direction of the normal vector and locally concentrates at the portions where the structure of the edge termination region 120 differs.

Further, the double-zone JTE structure 121 of the conventional structure has, with respect to the n-type column regions 131 and the p-type column regions 132 of the parallel pn layer 103, a portion orthogonal thereto and a portion parallel thereto. Thus, in an instance in which the double-zone JTE structure 121 is provided, at the portion where the double-zone JTE structure 121 is provided, the structure of the edge termination region 120 further partially differs concentrically at substantially a same distance from the outer periphery of the active region 110 in the direction of the normal vector. The portion of the double-zone JTE structure 121 where the structure is different with respect to the parallel pn layer 103 is also a location of electric field concentration.

On the other hand, in the first embodiment, in the edge termination region 20, the n-type column regions 33 and the p-type column regions 34 are disposed in concentric shapes surrounding the periphery of the active region 10, whereby the edge termination region 20 has a structure that is the same concentrically at substantially a same distance from the outer periphery of the active region 10 in the direction of the normal vector. Thus, unlike the conventional structure, the edge termination region 20 is free of locations that, in the direction of the normal vector, are concentrically a same distance from the outer periphery of the active region 10 and where electric field concentrates. Therefore, when the MOSFET is off, electric field applied to the edge termination region 20 may be distributed evenly in the direction of the normal vector according to distance from the outer periphery of the active region 10.

Further, in the first embodiment, the double-zone JTE structure 21 has only portions parallel to the n-type column regions 33 and the p-type column regions 34 of the second parallel pn layer 3b and is free of a portion having a structure different from that of the second parallel pn layer 3b. Therefore, even in an instance in which the double-zone JTE structure 21 is provided, the edge termination region 20 is free of locations that, in the direction of the normal vector, are concentrically a same distance from the outer periphery of the active region 10 and where electric field concentrates when the MOSFET is off, and electric field applied to the edge termination region 20 may be distributed evenly according to distance from the outer periphery of the active region 10, in the direction of the normal vector.

In the semiconductor substrate 40, epitaxial layers 42, 43 constituting the drift layer and the p-type base region 4 are sequentially deposited on a front surface of an n⁺-type starting substrate 41 that contains silicon carbide. The semiconductor substrate 40 has, as a front surface, a main surface having the p-type epitaxial layer 43 and, as a back surface (second main surface), a main surface having the n⁺-type starting substrate 41. The n⁺-type starting substrate 41 constitutes an n⁺-type drain region 1. The drift layer (the n-type epitaxial layer 42) is provided between and in contact with the p-type base region 4 and the n⁺-type drain region 1.

The second parallel pn layer 3b is provided from the border between the active region 10 and the edge termination region 20 to a position closer to the chip end than is the double-zone JTE structure 21. An outermost column region of the second parallel pn layer 3b is one of the p-type column regions 34. The second parallel pn layer 3b is in contact with the later-described p⁺-type extension portion 11a, the n⁺-type channel stopper region 25, and a normal n-type drift region 35. The second parallel pn layer 3b is exposed at the front surface of the semiconductor substrate 40 (the later-described second portion 40b), between the double-zone JTE structure 21 and the n⁺-type channel stopper region 25.

Of the p-type column regions 34 of the second parallel pn layer 3b, one of the p-type column regions 34 (a later-described JTE border p-type column region 34a) directly beneath (side facing the n⁺-type drain region 1) the double-zone JTE structure 21 may preferably satisfy later-described conditions for positioning relative to the border 24 between the p⁻-type region 22 and the p⁻-type region 23 of the double-zone JTE structure 21. A portion between a side surface of the semiconductor substrate 40 and the second parallel pn layer 3b is the normal n-type drift region 35 free of a SJ structure. An impurity concentration of the normal n-type drift region 35 is not more than the impurity concentration of the n-type column regions 31, 33.

Between the front surface of the semiconductor substrate 40 and the normal n-type drift region 35, the n⁺-type channel stopper region 25 is selectively provided apart from the second parallel pn layer 3b. The normal n-type drift region 35 and the n⁺-type channel stopper region 25 are provided along an outer periphery of the semiconductor substrate 40 and surround a periphery of the second parallel pn layer 3b. The normal n-type drift region 35 and the n⁺-type channel stopper region 25 are exposed at the side surface of the semiconductor substrate 40. Instead of the n⁺-type channel stopper region 25, a p⁺-type channel stopper region may be provided.

At least surface regions of the drift layer, at the surface thereof facing the front surface of the semiconductor substrate 40, constitute the SJ structure including the first and second parallel pn layers 3a, 3b. A portion of the drift layer between the first and second parallel pn layers 3a, 3b and the n⁺-type drain region 1 may be an n-type buffer region (n-type region that is not part of the SJ structure) 2. The n-type buffer region 2 is in contact with the first and second parallel pn layers 3a, 3b, the n⁺-type drain region 1, and the normal n-type drift region 35 that is not the SJ structure. An impurity concentration of the n-type buffer region 2 is not more than the impurity concentration of the n-type column regions 31, 33.

The n-type column regions 31, 33 and the p-type column regions 32, 34 reach the n-type buffer region 2 (in an instance in which the n-type buffer region 2 is omitted, the n⁺-type drain region 1) in a depth direction Z. Respective lengths of the n-type column regions 31, 33 and the p-type column regions 32, 34 in the depth direction Z are substantially equal. The respective lengths of the n-type column regions 31 and the p-type column regions 32 in the depth direction Z are each lengths from later-described p⁺-type regions 11, 12 to the n-type buffer region 2 (in an instance in which the n-type buffer region 2 is omitted, the n⁺-type drain region 1).

The respective lengths of the n-type column regions 33 and the p-type column regions 34 in the depth direction Z are from the double-zone JTE structure 21 or the later-described p⁺-type extension portion 11a to the n-type buffer region 2 (in an instance in which the n-type buffer region 2 is omitted, the n⁺-type drain region 1). The width Wn1 of the n-type column regions 31 in lateral direction thereof is wider than a width of the p⁺-type regions 11 in lateral direction thereof. The n-type column regions 31 may be in contact with the p⁻-type regions 12. The width Wp1 of the p-type column regions 32 in the lateral direction thereof is substantially equal to a width of the p⁺-type regions 12 in lateral direction thereof.

The p-type column regions 32 of the first parallel pn layer 3a are electrically connected to a source electrode 15 via the p⁺-type regions 12, the p-type base region 4, and p⁺⁺-type contact regions 6. In the second parallel pn layer 3b, of the p-type column regions 34, ones thereof disposed closer to the chip center than is an outer end of the double-zone JTE structure 21 are electrically connected to the source electrode 15, via a p-type base extension portion 4a and the p⁺-type extension portion 11a or via these regions and the double-zone JTE structure 21. In the second parallel pn layer 3b, the p-type column regions 34 disposed closer to the chip end than is the double-zone JTE structure 21 are electrically floating.

The trench gate structure is configured by the p-type base region (first semiconductor region) 4, n⁺-type source regions (second semiconductor regions) 5, the p⁺⁺-type contact regions 6, gate trenches (trenches) 7, gate insulating films 8, and gate electrodes 9. The p-type base region 4 is provided between the front surface of the semiconductor substrate 40 and the first parallel pn layer 3a. The p-type base region 4 is a portion of the p-type epitaxial layer 43 excluding the n⁺-type source regions 5 and the p⁺⁺-type contact regions 6. The p-type base region 4 extends from the active region 10 to a later-described recess sidewall 44.

The n⁺-type source regions 5 and the p⁺⁺-type contact regions 6 are each selectively provided between the front surface of the semiconductor substrate 40 and the p-type base region 4, in the active region 10. The n⁺-type source regions 5 and the p⁺⁺-type contact regions 6 are in contact with the p-type base region 4 and are exposed at the front surface of the semiconductor substrate 40. The n⁺-type source regions 5 and the p⁺⁺-type contact regions 6 being exposed at the front surface of the semiconductor substrate 40 means that these regions are in contact with the later-described source electrode (first electrode) 15, at a later-described first portion 40a of the front surface of the semiconductor substrate 40.

The n⁺-type source regions 5 and the p⁺⁺-type contact regions 6, for example, extend linearly along sidewalls of the gate trenches 7, in the second direction Y. The n⁺-type source regions 5 are disposed closer to the gate trenches 7 than are the p⁺⁺-type contact regions 6 and face the gate electrodes 9 via the gate insulating films 8 at the sidewalls of the gate trenches 7. The p⁺⁺-type contact regions 6 may be omitted. In this instance, instead of the p⁺⁺-type contact regions 6, the p-type base region 4 is exposed at the first portion 40a of the front surface of the semiconductor substrate 40.

The p⁺-type regions (second-conductivity-type high-concentration regions) 11, 12 are each selectively provided between the p-type base region 4 and the first parallel pn layer 3a. The p⁺-type regions 11, 12 are diffused regions formed by ion implantation in the n-type epitaxial layer 42. The p⁺-type regions 11, 12 are electrically connected to the source electrode 15, deplete when the MOSFET is off, and have a function of mitigating electric field closer to the bottoms of the gate trenches 7. The p⁺-type regions 11, 12 extend in a striped pattern along the sidewalls of the gate trenches 7, in the second direction Y.

The n-type column regions 31 extend between the p⁺-type regions 11, 12. Between the p⁺-type regions 11, 12, the n-type column regions 31 extend to and are in contact with the p-type base region 4. The p⁺-type regions 11 are disposed apart from the p-type base region 4 and face the bottoms of the gate trenches 7 in the depth direction Z. The p⁺-type regions 11, at a non-depicted portion, are connected to the p⁺-type regions 12. The p⁺-type regions 11 face and are in contact with the n-type column regions 31 in the depth direction Z. The p⁺-type regions 11 may be in contact with the gate insulating films 8 at the bottoms of the gate trenches 7.

Outermost ones of the p⁺-type regions 11 in the first direction X extend closer to the chip end than is the later-described recess sidewall 44 and are exposed at the later-described second portion 40b of the front surface of the semiconductor substrate 40. Being exposed at later-described second and third portions 40b, 40c of the front surface of the semiconductor substrate 40 means being in contact with the interlayer insulating film 14 above the front surface of the semiconductor substrate 40. The p⁺-type regions 12 are each disposed between an adjacent two of the gate trenches 7 and is in contact with the p-type base region 4 and apart from the p⁺-type regions 11 and the gate trenches 7. The p⁺-type regions 12 face and are in contact with the p-type column regions 32 in the depth direction Z.

Between the gate trenches 7, a non-depicted n-type current spreading region may be provided between and in contact with the p⁺-type regions 11, 12, the p-type base region 4, and the n-type column regions 31, and in the first direction X, reaches the sidewalls of the gate trenches 7. The n-type current spreading region is a so-called current spreading layer (CSL) that reduces carrier spreading resistance. An impurity concentration of the n-type current spreading region is at least equal to the impurity concentration of the n-type column regions 31.

The gate trenches 7 penetrate through the n⁺-type source regions 5 and the p-type base region 4 in the depth direction Z from the first portion 40a of the front surface of the semiconductor substrate 40 and reach the n-type column regions 31 (in an instance in which the n-type current spreading region is provided, the n-type current spreading region). The bottoms of the gate trenches 7 may terminate in the p⁺-type regions 11. The gate trenches 7 extend in a striped pattern in a direction parallel to the front surface of the semiconductor substrate 40 (here, the second direction Y). The gate electrodes 9 are provided in the gate trenches 7, via the gate insulating films 8.

The interlayer insulating film 14 is provided in an entire area of the front surface of the semiconductor substrate 40 and covers the gate electrodes 9. The source electrode 15 is in ohmic contact with the first portion 40a of the front surface of the semiconductor substrate 40 in contact holes of the interlayer insulating film 14 and is electrically connected to the p-type base region 4, the n⁺-type source regions 5, and the p⁺⁺-type contact regions 6. A drain electrode (second electrode) 16 is provided in an entire area of a back surface (back surface of the n⁺-type starting substrate 41) of the semiconductor substrate 40 and is electrically connected to the n⁺-type drain region 1.

A portion of the p-type epitaxial layer 43 is removed in the edge termination region 20, whereby the recess sidewall 44 is formed at the front surface of the semiconductor substrate 40. The front surface of the semiconductor substrate 40 has a portion (hereinafter, the first portion) 40a and a portion (hereinafter, the second portion) 40b separated by the recess sidewall 44, the first portion 40a being in the active region 10 and the second portion 40b being in the edge termination region 20 and recessed toward the n⁺-type drain region 1 as compared to the first portion 40a. The second portion 40b of the front surface of the semiconductor substrate 40 is the surface of the n-type epitaxial layer 42 exposed by the removal of the p-type epitaxial layer 43.

Devices of the active region 10 and the edge termination region 20 are separated by a portion (hereinafter, third portion, mesa edge forming the recess sidewall 44) 40c of the front surface of the semiconductor substrate 40, connecting the first portion 40a of the front surface of the semiconductor substrate 40 and the second portion 40b. In the edge termination region 20, a field oxide film may be provided between the front surface of the semiconductor substrate 40 and the interlayer insulating film 14. In the edge termination region 20, between the front surface of the semiconductor substrate 40 and the second parallel pn layer 3b, the p-type base region 4 and of the p⁺-type regions 11, one that faces the bottom of an outermost one (7a) of the gate trenches 7 extend from the active region 10.

Hereinafter, portions of the p-type base region 4 and the p⁺-type regions 11 extending in the edge termination region 20 are referred to as the p-type base extension portion 4a and the p⁺-type extension portion 11a, respectively. The p-type base extension portion 4a is exposed at the first portion 40a of the front surface of the semiconductor substrate 40. Between the first portion 40a of the front surface of the semiconductor substrate 40 and the p-type base extension portion 4a, a non-depicted p⁺⁺-type outer peripheral contact region may be provided. The p-type base extension portion 4a (in an instance in which the p⁺⁺-type outer peripheral contact region is provided, the p⁺⁺-type outer peripheral contact region) is in contact with the source electrode 15.

The p-type base extension portion 4a and the p⁺-type extension portion 11a extend along the border between the active region 10 and the edge termination region 20 and surround the periphery of the active region 10. The p⁺-type extension portion 11a is provided between and in contact with the p-type base extension portion 4a and the second parallel pn layer 3b. The p⁺-type extension portion 11a is connected to ends of all the p⁺-type regions 11, 12 of the active region 10. Further, the p⁺-type extension portion 11a extends closer to the chip end than is the recess sidewall 44 of the front surface of the semiconductor substrate 40 and is exposed at the second portion 40b of the front surface of the semiconductor substrate.

A non-depicted gate runner is provided between the active region 10 and the double-zone JTE structure 21. The gate runner includes a gate polysilicon wiring layer provided on the first portion 40a of the front surface of the semiconductor substrate 40, via a non-depicted field oxide film. The gate polysilicon wiring layer is covered by the interlayer insulating film 14. The gate polysilicon wiring layer is connected to the gate electrodes 9 of all the unit cells of the active region 10. The gate runner electrically connects the gate electrodes 9 and a gate pad (electrode pad, not depicted).

In the edge termination region 20, two p-type regions (the p⁻-type region 22, the p⁻⁻-type region 23) configuring the double-zone JTE structure 21 are each selectively provided in the semiconductor substrate 40 at the second portion 40b of the front surface thereof, in the n-type epitaxial layer 42, and the n⁺-type channel stopper region 25 is selectively provided apart from the double-zone JTE structure 21, closer to the chip end than are these two p-type regions. The double-zone JTE structure 21 is provided between the second portion 40b of the front surface of the semiconductor substrate 40 and the second parallel pn layer 3b, and is in contact with the second parallel pn layer 3b.

The p⁻-type region 22 is adjacent to the p⁺-type extension portion 11a and closer to the chip end than is the p⁺-type extension portion 11a. The p⁻-type region 23 is adjacent to the p⁻-type region 22 and closer to the chip end than is the p⁻-type region 22. The p⁻-type region 22 and the p⁻⁻-type region 23 are fixed to the potential of the source electrode 15, via the p⁺-type extension portion 11a and the p-type base extension portion 4a. The p⁻-type region 22, the p⁻⁻-type region 23, and the n⁺-type channel stopper region 25 are diffused regions formed by ion implantation in the n-type epitaxial layer 42 and are exposed at the second portion 40b of the front surface of the semiconductor substrate 40.

The n⁺-type channel stopper region 25 is provided between the second portion 40b of the front surface of the semiconductor substrate 40 and the normal n-type drift region 35. Between the double-zone JTE structure 21 and the n⁺-type channel stopper region 25, the second parallel pn layer 3b and the normal n-type drift region 35 are exposed at the second portion 40b of the front surface of the semiconductor substrate 40. The normal n-type drift region 35 is in contact with the second parallel pn layer 3b and surrounds the periphery of the second parallel pn layer 3b. An impurity concentration of the normal n-type drift region 35 is not more than the impurity concentration of the n-type column regions 31.

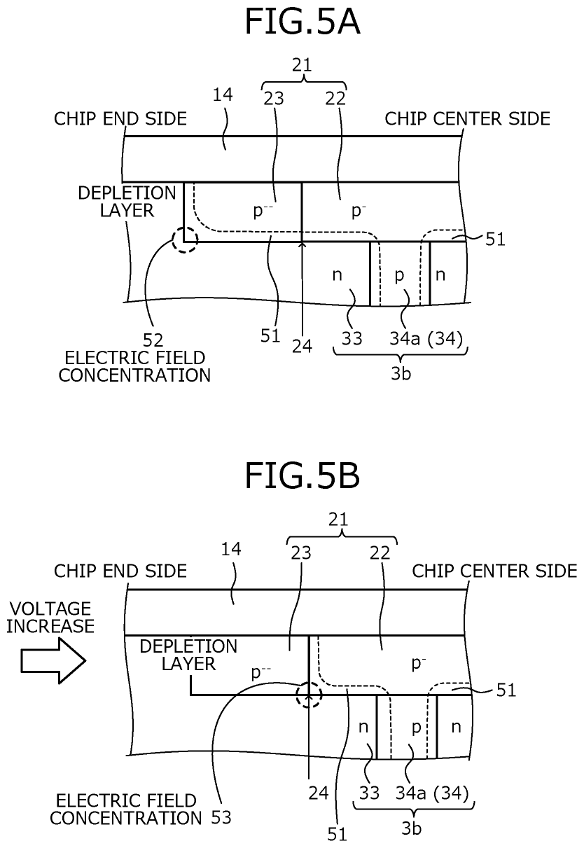

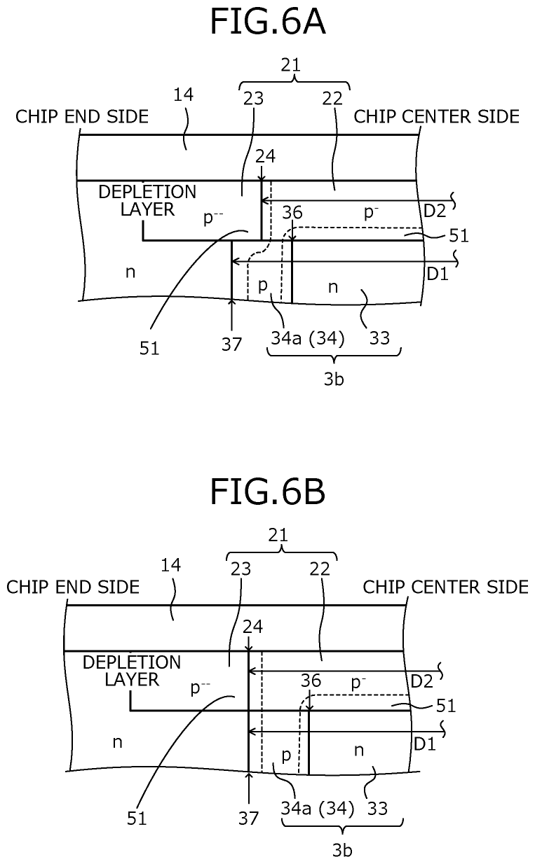

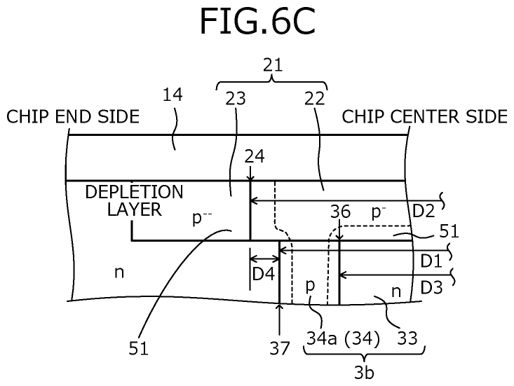

A positional relationship between the p-type column regions 34 and the double-zone JTE structure 21 in the edge termination region 20 is described. FIGS. 5A and 5B are diagrams for describing a mechanism of electric field concentration at the double-zone JTE structure. FIGS. 6A, 6B, and 6C are diagrams for describing the positional relationship between the p-type column regions of the edge termination region and the double-zone JTE structure of the first embodiment. In FIGS. 5A, 5B, 6A, 6B, and 6C, of the p-type column regions 34 of the edge termination region 20, only a JTE border p-type column region (border column region) 34a is depicted while others of the p-type column regions 34 are not depicted. Further, in FIGS. 5A, 5B, 6A, 6B, and 6C, spreading of a depletion layer is indicated by a fine dashed line. The depletion layer is between two fine dashed lines.

As depicted in FIGS. 5A and 5B, when voltage (forward voltage) that is positive with respect to the source electrode 15 is applied to the drain electrode 16 and voltage lower than a gate threshold voltage is applied to the gate electrodes 9, in the edge termination region 20, the pn junctions between the p-type column regions 34 and the n-type column regions 33 of the second parallel pn layer 3b, and pn junctions between the p⁻-type region 22 and the p⁻⁻-type region 23 of the double-zone JTE structure 21 and the n-type column regions 33 of the second parallel pn layer 3b are reverse biased, and a depletion layer spreads 51 from the pn junctions to the p-type column regions 34, the p⁻-type region 22, and the p⁻⁻-type region 23.

When the depletion layer 51 spreads in the p⁻-type region 22 and the p⁻-type region 23 of the double-zone JTE structure 21, electric field concentration 52 occurs at an outer lower (facing the n⁺-type drain region 1) corner portion of the p⁻⁻-type region 23, which, of these regions, is relatively closer to the chip end (FIG. 5A). When forward voltage between a source and drain increases, depletion further progresses, the p⁻⁻-type region 23 is completely depleted, and when the depletion layer 51 spreads from the p⁻⁻-type region 23 to the p⁻-type region 22, electric field concentration 53 occurs at a lower end portion of the border 24 between the p⁻-type region 22 and the p⁻⁻-type region 23 (FIG. 5B).

As described above, the n-type column regions 33 and the p-type column regions 34 of the edge termination region 20, and the p⁻-type region 22 and the p⁻⁻-type region 23 of the double-zone JTE structure 21 are disposed in concentric shapes that surround the periphery of the active region 10 and thus, the edge termination region 20 has the same structure concentrically at substantially a same distance from the outer periphery of the active region 10, in the direction of the normal vector. At the outer lower corner portion of the p⁻-type region 23 and the lower end portion of the border 24 between the p⁻-type region 22 and the p⁻⁻-type region 23, concentration (52, 53) of the electric field uniformly occurs along an entire periphery of the double-zone JTE structure 21.

Thus, the second parallel pn layer 3b is suitably set so that electric field is mitigated at locations of the electric field concentration 52, 53 in the edge termination region 20, whereby the breakdown voltage of the edge termination region 20 may be further enhanced. For example, of the p-type column regions 34 of the second parallel pn layer 3b, one (hereinafter, the JTE border p-type column region 34a) that is closest to the border 24 between the p⁻-type region 22 and the p⁻⁻-type region 23 of the double-zone JTE structure 21, preferably, may be disposed so as to satisfy conditions concerning a positional relationship thereof with the border 24, depicted in FIGS. 6A, 6B, and 6C.

As depicted in FIG. 6A, preferably, the JTE border p-type column region 34a may be disposed directly beneath the lower end portion of the border 24 between the p⁻-type region 22 and the p⁻⁻-type region 23 of the double-zone JTE structure 21 and in contact with the p⁻-type region 22 and the p⁻⁻-type region 23. Further, as depicted in FIG. 6B, preferably, the JTE border p-type column region 34a may be disposed in contact with the p⁻-type region 22, so as that an outer side-surface 37 thereof is at a position that is the same as that of the border 24 between the p⁻-type region 22 and the p⁻⁻-type region 23 of the double-zone JTE structure 21 in the direction of the normal vector.

Further, as depicted in FIG. 6C, preferably, the JTE border p-type column region 34a may be disposed in contact with the p⁻-type region 22 so that the outer side-surface 37 is positioned closer to chip center in the direction of the normal vector than is the border 24 between the p⁻-type region 22 and the p⁻-type region 23 of the double-zone JTE structure 21 and a distance D4 from the outer side-surface 37 to the border 24 is less than 1 μm. In other words, in terms of the positional relationship with the border 24 between the p⁻-type region 22 and the p⁻⁻-type region 23 of the double-zone JTE structure 21, preferably, the JTE border p-type column region 34a is disposed so as to satisfy expression (1) or expression (2) below.

D1≥D2>D3 (1)

D2>D1, and, D2−D1<1 μm (2)

Where, D1 is a distance from the active region 10 to the outer side-surface 37 of the JTE border p-type column region 34a, in the direction of the normal vector. D2 is a distance from the active region 10 to the border 24 between the p⁻-type region 22 and the p⁻⁻-type region 23 of the double-zone JTE structure 21, in the direction of the normal vector. Therefore, (D2−D1) is a distance from the border 24 between the p⁻-type region 22 and the p⁻⁻-type region 23 of the double-zone JTE structure 21 to the outer side-surface 37 of the JTE border p-type column region 34a, in the direction of the normal vector.

D3 is a distance from the active region 10 in the direction of the normal vector to an inner side-surface 36 of the JTE border p-type column region 34a. The inner side-surface 36 of the JTE border p-type column region 34a is an interface between the JTE border p-type column region 34a and one of the n-type column regions 33 adjacent thereto and closer to the chip center than is the JTE border p-type column region 34a. The outer side-surface 37 of the JTE border p-type column region 34a is an interface between the JTE border p-type column region 34a and one of the n-type column regions 33 adjacent thereto and closer to the chip end than is the JTE border p-type column region 34a.

The JTE border p-type column region 34a is disposed closer to the border 24 between the p⁻-type region 22 and the p⁻⁻-type region 23 of the double-zone JTE structure 21 so as to satisfy expression (1) or expression (2), whereby the electric field concentration 53 at the lower end portion of the border 24 between the p⁻-type region 22 and the p⁻⁻-type region 23 of the double-zone JTE structure 21 (FIG. 5B) may be suppressed. As a result, the breakdown voltage of the edge termination region 20 may be further enhanced and thus, resistance to destruction may be further enhanced.

Operation of the silicon carbide semiconductor device 50 according to the present embodiment is described. When voltage (forward voltage) that is positive with respect to the source electrode 15 is applied to the drain electrode 16 and voltage that is at least equal to the gate threshold voltage is applied to the gate electrodes 9, a channel (n-type inversion layer) is formed at portions of the p-type base region 4 along the sidewalls of the gate trenches 7. As a result, a main current (drift current) flows in a direction from the n⁺-type drain region 1, through the channel to the n⁺-type source regions 5 and the SiC-MOSFET (the silicon carbide semiconductor device 50) turns on.

On the other hand, when forward voltage is applied between the source and drain and voltage that that is lower than the gate threshold voltage is applied to the gate electrodes 9, pn junctions (main junctions of the active region 10) between the p⁺-type regions 11, 12 and the p-type base region 4 and the n-type column regions 31 of the first parallel pn layer 3a are reverse biased, whereby flow of the main current ceases and the SiC-MOSFET maintains an off-state. The main junctions (pn junctions) of the active region 10 are reverse biased, whereby a depletion layer spreads from the pn junctions and a predetermined breakdown voltage of the active region 10 is ensured.

Further, when the SiC-MOSFET is off, the pn junctions between the p-type column regions 32, 34 and the n-type column regions 31, 33 are reverse biased and a depletion layer spreads from the pn junctions, whereby the breakdown voltage is borne by the first and second parallel pn layers 3a, 3b. As a result, a predetermined breakdown voltage that exceeds a breakdown voltage that may be realized by the impurity concentration (the n-type column regions 31, 33) of the drift layer is ensured. Further, electric field of the edge termination region 20 is distributed by the double-zone JTE structure 21 and the p-type column regions 34 of the second parallel pn layer 3b and thus, the breakdown voltage of the edge termination region 20 may be enhanced.

Further, when the SiC-MOSFET is off, in the edge termination region 20, the pn junctions between the p-type column regions 34 and the n-type column regions 33 of the second parallel pn layer 3b, and pn junctions between the p⁻-type region 22 and the p⁻⁻-type region 23 of the double-zone JTE structure 21 and the n-type column regions 33 of the second parallel pn layer 3b are reverse biased, and the depletion layer 51 spreads from the pn junctions to the p-type column regions 34, the p⁻-type region 22, and the p⁻⁻-type region 23. At this time, concentration (52, 53) of the electric field may occur locally at the double-zone JTE structure 21 (refer to FIGS. 5A and 5B).

Further, the JTE border p-type column region 34a satisfies expression (1) or expression (2) concerning the positional relationship thereof with the border 24 between the p⁻-type region 22 and the p⁻⁻-type region 23 of the double-zone JTE structure 21, whereby the electric field concentration 53 at the lower end portion of the border 24 between the p⁻-type region 22 and the p⁻-type region 23 of the double-zone JTE structure 21 may be suppressed. As a result, when the MOSFET is off, electric field applied to the edge termination region 20 may be further mitigated and thus, the breakdown voltage of the edge termination region 20 may be further enhanced.

A method of manufacturing the silicon carbide semiconductor device 50 according to the first embodiment is described. First, the drift layer, which includes the first and second parallel pn layers 3a, 3b, is formed on the front surface of the n⁺-type starting substrate (semiconductor wafer) 41 constituting the n⁺-type drain region 1. At this time, for example, a multistage epitaxial method is used in which the n-type epitaxial layer 42 constituting the drift layer is divided into multiple stages (sessions) and at each stage of epitaxial growth, a p-type impurity such as aluminum (Al) is ion-implanted in the grown n-type epitaxial layer, whereby portions constituting the p-type column regions 32, 34 of the first and second parallel pn layers 3a, 3b are selectively formed.

Portions of the n-type epitaxial layer 42 free of ion implantation and left as an n-type between the p-type column regions 32, which are adjacent to one another, constitute the n-type column regions 31, 33 of the first and second parallel pn layers 3a, 3b. An entire portion of the n-type epitaxial layer 42, between the first and second parallel pn layers 3a, 3b and the n⁺-type starting substrate 41 may be free of ion implantation and left as the n-type buffer region 2. Hereinafter, an instance in which the n-type buffer region 2 is provided is described as an example. Portions free of ion implantation and left as an n-type between the second parallel pn layer 3b and the chip end (end of portion constituting the semiconductor chip) constitute the normal n-type drift region 35.

The n-type column regions 31, 33 may be formed by ion implantation of an n-type impurity. In this instance, instead of the n-type epitaxial layer 42, a non-doped epitaxial layer or n⁻-type epitaxial layer is epitaxially grown in multiple stages. In an instance in which a non-doped epitaxial layer is epitaxially grown in multiple stages, the n-type buffer region 2 and the n-type drift region 35 are formed by ion implantation of an n-type impurity. In an instance in which an n⁻-type epitaxial layer is epitaxially grown in multiple stages, the n-type drift region 35 and the n-type buffer region 2 of lower impurity concentrations than that of the n-type column regions 31, 33 may be formed.

Next, by ion implantation, in the n-type epitaxial layer 42, at the surface thereof, the p⁺-type regions 11, 12 are selectively formed adjacent to the n-type column regions 31 and the p-type column regions 32 of the first parallel pn layer 3a in the depth direction Z, respectively. Further, concurrently with the p⁺-type regions 11, the p⁺-type extension portion 11a is formed adjacent to the second parallel pn layer 3b in the depth direction Z. In an uppermost one of the n-type epitaxial layers of the n-type epitaxial layer 42 formed by multiple stages of epitaxial growth, the p⁺-type regions 11, 12 and the p⁺-type extension portion 11a alone may be formed, and between the p⁺-type regions 11, 12 that are adjacent to one another, the non-depicted n-type current spreading region may be formed by ion implantation.

Next, on the n-type epitaxial layer 42, the p-type epitaxial layer 43 constituting the p-type base region 4 is epitaxially grown. Thus, the semiconductor substrate (semiconductor wafer) 40 in which the epitaxial layers 42, 43 are sequentially stacked on the n⁺-type starting substrate 41 and in the n-type epitaxial layer 42, the first and second parallel pn layers 3a, 3b are included is fabricated. Next, a portion of the p-type epitaxial layer 43 in the edge termination region 20 is removed by etching, thereby forming at the front surface of the semiconductor substrate 40, the recess sidewall 44 where a portion (the second portion 40b) of the front surface of the semiconductor substrate 40 in the edge termination region 20 becomes lower than a portion (the first portion 40a) thereof in the active region 10.

The n-type epitaxial layer 42 is exposed at the second portion 40b of the front surface of the semiconductor substrate 40 newly formed in the edge termination region 20. A portion (the third portion 40c) of the front surface of the semiconductor substrate 40 between the first portion 40a and the second portion 40b thereof, for example, may form an obtuse angle (sloped surface) with respect to the first and second portions 40a, 40b or may form a substantially right angle (orthogonal surface) therewith. The p-type base region 4 and the p⁺-type extension portion 11a are exposed at the second and third portions 40b, 40c of the front surface of the semiconductor substrate 40. The n-type epitaxial layer 42 may be slightly removed with the p-type epitaxial layer 43 by the etching when forming the recess sidewall 44.

Next, the n⁺-type source regions 5, the p⁺⁺-type contact regions 6, the double-zone JTE structure 21 (the p⁻-type region 22, the p⁻⁻-type region 23), and the n⁺-type channel stopper region 25 are each selectively formed by ion implantation. The n⁺-type source regions 5 and the p⁺⁺-type contact regions 6 are each selectively formed in the p-type epitaxial layer 43, at the surface thereof. The p⁺⁺-type outer peripheral contact region may be formed concurrently with the p⁺⁺-type contact regions 6. Portions of the p-type epitaxial layer 43, excluding the n⁺-type source regions 5, the p⁺⁺-type contact regions 6, and the p⁺⁺-type outer peripheral contact region constitute the p-type base region 4 and the p-type base extension portion 4a.

The double-zone JTE structure 21 and the n⁺-type channel stopper region 25 are each selectively formed in the n-type epitaxial layer 42, at the surface thereof exposed at the second portion 40b of the front surface of the semiconductor substrate 40, in the edge termination region 20. A sequence in which the n⁺-type source regions 5, the p⁺⁺-type contact regions 6, the p⁺⁺-type outer peripheral contact region, the double-zone JTE structure 21, and the n⁺-type channel stopper region 25 are formed may be interchanged. Further, the n⁺-type source regions 5, the p⁺⁺-type contact regions 6, and the p⁺⁺-type outer peripheral contact region may be formed before formation of the recess sidewall 44 of the front surface of the semiconductor substrate 40.

Next, a heat treatment for activating the impurities ion-implanted in the epitaxial layers 42, 43 is performed. The heat treatment may be performed each time a diffused region is formed by ion implantation. Next, the gate trenches 7 that penetrate through the n⁺-type source regions 5 and the p-type base region 4, from the front surface of the semiconductor substrate 40, and reach the p⁺-type regions 11 are formed. Next, by a general method, the gate insulating films 8, the gate electrodes 9, the interlayer insulating film 14, the source electrode 15, and the drain electrode 16 are formed. Thereafter, the semiconductor wafer (the semiconductor substrate 40) is diced (cut) into individual chips, whereby the silicon carbide semiconductor device 50 depicted in FIGS. 1 to 4 is completed.

In the method of manufacturing the silicon carbide semiconductor device 50 according to the first embodiment described above, instead of the multistage epitaxial method, the first and second parallel pn layers 3a, 3b may be formed using a trench filling epitaxial method. In an instance in which a trench filling epitaxial method is used, trenches (SJ trenches) of a depth equal to a length of the p-type column regions 32, 34 in the depth direction Z are formed in the n-type epitaxial layer 42, portions constituting the n-type column regions 31, 33 are left, and the SJ trenches are embedded with a p-type epitaxial layer that constitutes the p-type column regions 32, 34, whereby the first and second parallel pn layers 3a, 3b are formed.

As described above, according to the first embodiment, the n-type column regions and the p-type column regions of the edge termination region are disposed in concentric shapes surrounding the periphery of the active region and the edge termination region has the same structure concentrically at a same distance from the outer periphery of the active region in the direction of the normal vector. Thus, electric field applied to the edge termination region when the MOSFET is off may be evenly distributed according to distance from the outer periphery of the active region in the direction of the normal vector and the breakdown voltage of the edge termination region may be enhanced. As a result, locations where avalanche breakdown occurs may be changed to the active region, which has a large area and occupies a majority of the area (surface area) of the semiconductor substrate, and thus, resistance to destruction may be enhanced.

Further, according to the first embodiment, the n-type column regions and the p-type column regions of the edge termination region are disposed in concentric shapes surrounding the periphery of the active region, whereby the double-zone JTE structure is configured by only portions parallel to the n-type column regions and the p-type column regions of the edge termination region and has the same structure with respect to the second parallel pn layer of the edge termination region. Thus, even in an instance in which the double-zone JTE structure is provided, electric field applied to the edge termination region when the MOSFET is off may be evenly distributed according to distance from the periphery of the active region in the direction of the normal vector and the breakdown voltage of the edge termination region may be enhanced.

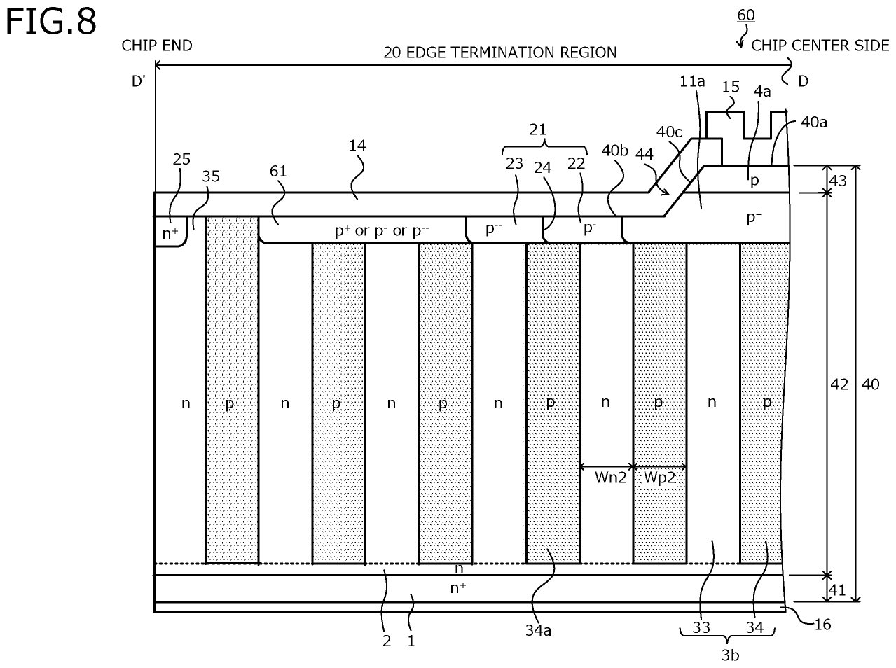

Next, a structure of a silicon carbide semiconductor device according to a second embodiment is described. FIG. 7 is a plan view depicting a layout when the silicon carbide semiconductor device according to the second embodiment is viewed from a front side of a semiconductor substrate thereof. FIG. 8 is a cross-sectional view depicting the structure along cutting line D-D′ in FIG. 7. Cross-sections of the structure along cutting line A-A′, cutting line B-B′, and cutting line C-C′ in FIG. 7 are the same as those in FIGS. 2 to 4, respectively. In FIG. 7, p-type connecting regions 61 are indicated by hatching different from that of the p-type column regions 32, 34.

A silicon carbide semiconductor device 60 according to the second embodiment differs from the silicon carbide semiconductor device 50 according to the first embodiment (refer to FIGS. 1 to 4) in that in the second parallel pn layer 3b, all the p-type column regions 34 disposed closer to the chip end than is the double-zone JTE structure 21 are partially connected by the p-type regions (hereinafter, p-type connecting regions (second-conductivity-type connecting regions)) 61 and are electrically connected to the source electrode 15, via the p-type connecting regions 61.

In the second embodiment, the p-type connecting regions 61 are provided between the double-zone JTE structure 21 and the n⁺-type channel stopper region 25 and are apart from the n⁺-type channel stopper region 25. Closer to the chip end than is the double-zone JTE structure 21, the p-type connecting regions 61 are provided between the second portion 40b of the front surface of the semiconductor substrate 40 and the second parallel pn layer 3b, and are in contact with the n-type column regions 33 and the p-type column regions 34 of the second parallel pn layer 3b.

The p-type connecting regions 61 are adjacent to the p⁻⁻-type region 23 of the double-zone JTE structure 21 and closer to the chip end than is the p⁻-type region 23. All the p-type column regions 34 that are disposed closer to the chip end than is the double-zone JTE structure 21 are electrically connected to the source electrode 15, via the p-type connecting regions 61, the double-zone JTE structure 21 (the p⁻-type region 22, the p⁻⁻-type region 23), the p-type base extension portion 4a, and the p⁺-type extension portion 11a.

An impurity concentration of the p-type connecting regions 61, for example, is substantially equal to an impurity concentration of the p⁺-type extension portion 11a, the p⁻-type region 22, or the p⁻⁻-type region 23. The p-type connecting regions 61 partially connect all the p-type column regions 34 that are disposed closer to the chip end than is the double-zone JTE structure 21 and may electrically connect the p-type column regions 34 to the source electrode 15; an arrangement and shape thereof in a plan view may be suitably changed.

For example, the p-type connecting regions 61 may be selectively provided, respectively, at four corner portions (vicinity of vertices of a rectangle) of the semiconductor substrate 40, which has a substantially rectangular shape in a plan view. The p-type connecting regions 61 may extend linearly in the direction of the normal vector, crossing all the p-type column regions 34 that are disposed closer to the chip end than is the double-zone JTE structure 21. Outer ends of the p-type connecting regions 61 may be in contact with an outermost one of the p-type column regions 34 or may terminate in the outermost one of the p-type column regions 34.

A method of manufacturing the silicon carbide semiconductor device 60 according to the second embodiment may be implemented by forming the p-type connecting regions 61 concurrently with the p⁺-type extension portion 11a, the p⁻-type region 22, or the p⁻⁻-type region 23 in the method of manufacturing the silicon carbide semiconductor device 50 according to the first embodiment.

As described above, according to the second embodiment, all the p-type column regions that are disposed closer to the chip end than is the double-zone JTE structure are partially connected by the p-type connecting regions, whereby effects similar to those of the first embodiment may be obtained.

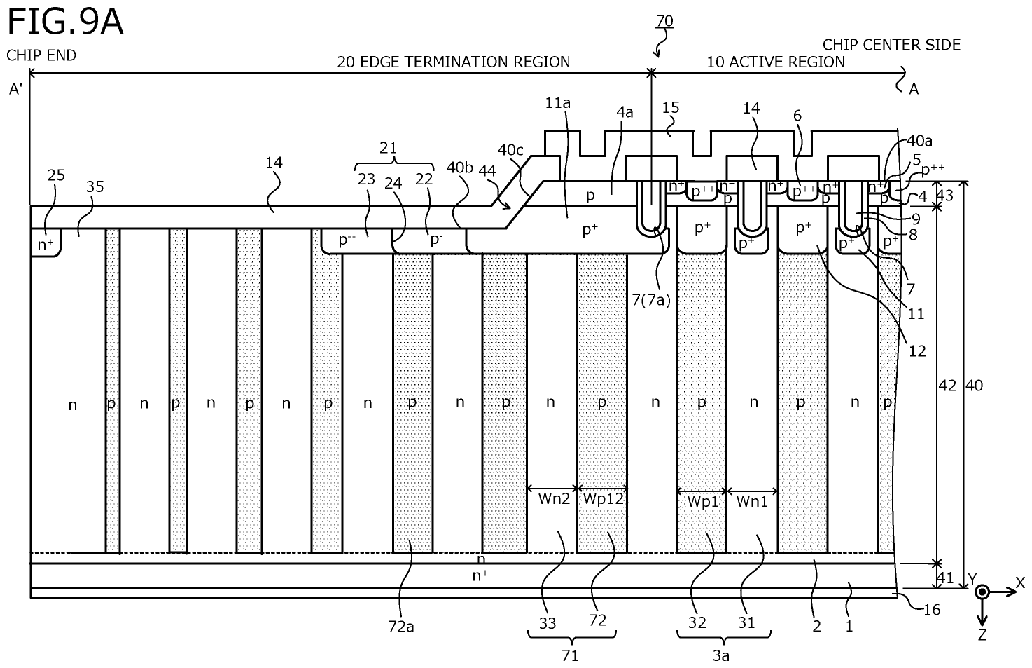

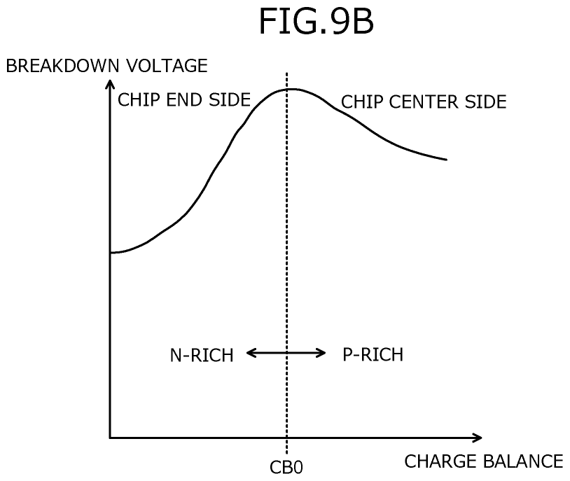

Next, a structure of a silicon carbide semiconductor device according to a third embodiment is described. FIG. 9A is a cross-sectional view of the structure of the silicon carbide semiconductor device according to the third embodiment. FIG. 9A corresponds to a cross-section of the structure along cutting line A-A′ in FIG. 1. FIG. 9B is a characteristics diagram depicting a relationship between breakdown voltage and charge balance in the direction of the normal vector, in the second parallel pn layer in FIG. 9A. A silicon carbide semiconductor device 70 according to the third embodiment differs from the silicon carbide semiconductor device 50 according to the first embodiment (refer to FIGS. 1 to 4) in that p-type column regions 72 of a second parallel pn layer 71 of the edge termination region 20, each has a different width Wp12 in a lateral direction thereof and the p-type column regions 72 are disposed in descending order of the width Wp12, in a direction from the chip center to the chip end.

In the third embodiment, the second parallel pn layer 71 of the edge termination region 20 is formed by the n-type column regions 33 and the p-type column regions 72 that are disposed adjacently and repeatedly alternate with one another, in concentric shapes surrounding the periphery of the active region 10. In the second parallel pn layer 71, the width Wn2 of all the n-type column regions 33 in the lateral direction thereof is substantially the same and a width Wp12 of each of the p-type column regions 72 in the lateral direction thereof is different and the p-type column regions 72 are arranged in descending order of the width Wp12 in a direction from the chip center to the chip end. Other than the width Wp12 of the p-type column regions 72 in the lateral direction thereof, configuration of the second parallel pn layer 71 is the same as that of the second parallel pn layer 3b of the first embodiment.

The second parallel pn layer 71 is relatively p-rich on an inner side and relatively n-rich on an outer side. P-rich is a state in which an amount of charge expressed by a product obtained by multiplying carrier concentration and the width in the lateral direction of the p-type column regions is greater than an amount of charge expressed by a product obtained by multiplying carrier concentration and the width in the lateral direction of the n-type column regions. N-rich is a state in which an amount of charge expressed by a product obtained by multiplying the carrier concentration and the width in the lateral direction of the n-type column regions is greater than an amount of charge expressed by a product obtained by multiplying the carrier concentration and the width in the lateral direction of the p-type column regions.

The inner side of the second parallel pn layer 71 is relatively p-rich, whereby the breakdown voltage may be reduced to a greater extend in an inner side of the edge termination region 20 than in an outer side thereof and thus, a structure is possible in which avalanche breakdown in the active region 10 is further facilitated. Further, the outer side of the second parallel pn layer 71 is relatively n-rich and thus, the p⁻⁻-type region 23 of the double-zone JTE structure 21 more easily depletes sooner and the electric field concentration 52 (refer to FIG. 5A) at the outer lower corner portion of the p⁻⁻-type region 23 may be suppressed.

Further, in the second parallel pn layer 71, at only one predetermined location CB0 of an inner portion thereof, equilibrium between the charge of the n-type column regions and the charge of the p-type column regions 72 is generally maintained while the second parallel pn layer 71 becomes increasingly p-rich in a direction to the chip center from the location CB0 and becomes increasingly n-rich in a direction to the chip end from the location CB0. The breakdown voltage of the edge termination region 20 is highest at the location CB0 where equilibrium of the charge of the second parallel pn layer 71 is generally maintained, and gradually decreases in the direction to the chip center (p-rich side) from the location CB0 and in the direction to the chip end (n-rich side) from the location CB0 (refer to FIG. 9B).

Furthermore, as the p-rich state increases in the direction from the location CB0 where the equilibrium of the charge of the second parallel pn layer 71 is generally maintained to the chip center (the active region 10 side), the occurrence of avalanche breakdown at ends of the p-type column regions 72 facing the n⁺-type drain region 1 becomes dominant, and decreases in the breakdown voltage from the location CB0 where the equilibrium of the charge of the second parallel pn layer 71 is generally maintained becomes more gradual in a direction to the p-rich side. As a result, without excessive decrease of the breakdown voltage of the active region 10, a location where avalanche breakdown occurs is the active region 10 and thus, as a result, the device itself may ensure the breakdown voltage.

Other than the width Wp12 of the JTE border p-type column region 72a in the lateral direction thereof, the JTE border p-type column region 72a being closest to the border 24 between the p⁻-type region 22 and the p⁻⁻-type region 23 of the double-zone JTE structure 21, of the p-type column regions 72 of the second parallel pn layer 71, configuration of the JTE border p-type column region 72a is the same as that of the JTE border p-type column region 34a of the first embodiment. The second embodiment may be applied to the silicon carbide semiconductor device 70 according to the third embodiment, and all the p-type column regions 72 that are closer to the chip end than is the double-zone JTE structure 21 may be partially connected by the p-type connecting regions 61 (refer to FIGS. 7 and 8).

A method of manufacturing the silicon carbide semiconductor device 70 according to the third embodiment may be implemented by suitably changing an opening pattern of an ion implantation mask for forming the p-type column regions 32, 72 in the method of manufacturing the silicon carbide semiconductor device 50 according to the first embodiment.

As described above, according to the third embodiment, the p-type column regions of the second parallel pn layer are disposed in descending order of width in lateral direction thereof, in a direction from the chip center to the chip end. As a result, concentration of electric field at the double-zone JTE structure may be suppressed and thus, the structure may further facilitate avalanche breakdown in the active region and effects similar to those of the first and second embodiments may be obtained.

Further, according to the third embodiment, the p-type column regions are disposed in descending order of width in the lateral direction thereof and thus, the p-type impurity concentration of the second parallel pn layer effectively decreases in a direction from the chip center to the chip end. Thus, effects similar to those of a spatial modulation JTE structure are expected and with increasing proximity to the chip end, electric field is suppressed. As a result, the breakdown voltage of the edge termination region is enhanced.

The spatial modulation JTE structure is a JTE structure in which p-type regions (p⁻-type region, p⁻⁻-type region) of different impurity concentrations and surrounding the periphery of the active region in concentric shapes are disposed in descending order of width, in the direction of the normal vector and are disposed in multiple units so that an interval between one of the p-type regions and an adjacent one of the p-type regions closer to the chip center is wider the closer the one of the p-type regions is to the chip end, whereby the p-type impurity concentration of the JTE structure decreases stepwise in a direction from the chip center to the chip end.

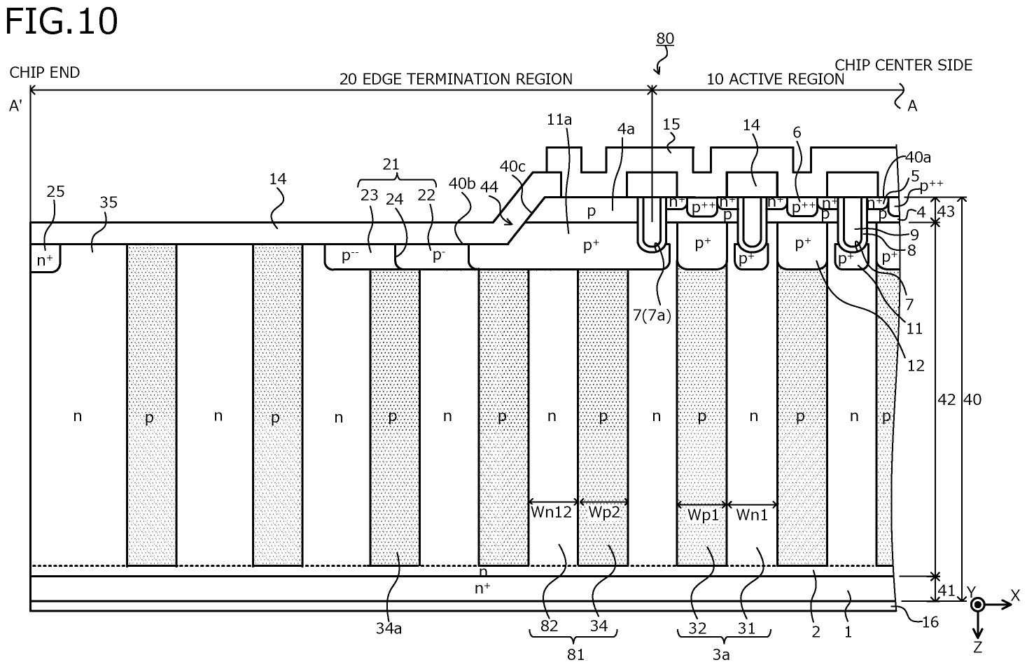

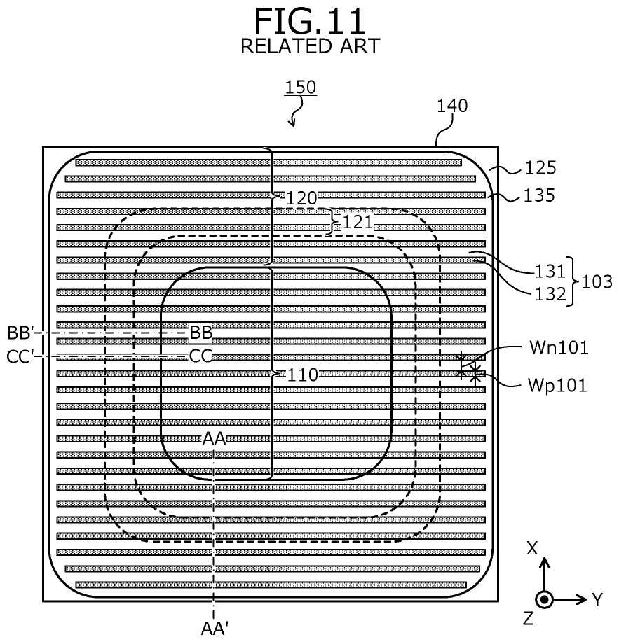

Next, a structure of a silicon carbide semiconductor device according to a fourth embodiment is described. FIG. 10 is a cross-sectional view depicting the structure of the silicon carbide semiconductor device according to the fourth embodiment. FIG. 10 corresponds to a cross-section of the structure along cutting line A-A′ in FIG. 1. In FIG. 10, a relationship between breakdown voltage and the charge balance in the direction of the normal vector in the second parallel pn layer is similar to that depicted in FIG. 9B. A silicon carbide semiconductor device 80 according to the fourth embodiment differs from the silicon carbide semiconductor device 50 according to the first embodiment (refer to FIGS. 1 to 4) in that the edge termination region 20, n-type column regions 82 of a second parallel pn layer 81 each has a different width Wn12 in a lateral direction thereof and the n-type column regions 82 are disposed in ascending order of the width Wn12, in a direction from the chip center to the chip end.

In the fourth embodiment, the second parallel pn layer 81 of the edge termination region 20 is formed by the n-type column regions 82 and the p-type column regions 34 that are disposed adjacently and repeatedly alternate with one another in concentric shapes surrounding the periphery of the active region 10. In the second parallel pn layer 81, the width Wp2 of all the p-type column regions 34 in lateral direction thereof is substantially the same and the width Wn12 of each of the n-type column regions 82 in the lateral direction thereof is different and the n-type column regions 82 are disposed in ascending order of the width Wn12, in a direction from the chip center to the chip end. Other than the width Wn12 of the n-type column regions 82 in lateral direction thereof, configuration of the second parallel pn layer 81 is similar to that of the second parallel pn layer 3b of the first embodiment.

In other words, an interval between an adjacent two of the p-type column regions 34 is wider the closer the adjacent two of the p-type column regions 34 are to the chip end. As a result, in the fourth embodiment as well, similarly to the second parallel pn layer 71 of the third embodiment (refer to FIGS. 9A and 9B), the second parallel pn layer 81 is p-rich in an inner side thereof and n-rich in an outer side thereof. Thus, similarly to the third embodiment, the structure may further facilitate avalanche breakdown in the active region 10. Further, the electric field concentration 52 at the outer lower corner portion of the p⁻⁻-type region 23 (refer to FIG. 5A) may be suppressed.

The closer the p-type column regions 34 of the width Wp2 in lateral direction thereof are disposed to the chip end, the wider is the interval therebetween and thus, the p-type impurity concentration of the second parallel pn layer 81 effectively decreases in a direction from the chip center to the chip end. Thus, similarly to the third embodiment, an effect similar to that of a spatial modulation JTE structure may be expected, and electric field in a direction from the chip center to the chip end is suppressed. As a result, breakdown voltage of the termination region is enhanced.

The second embodiment may be applied to the silicon carbide semiconductor device 80 according to the fourth embodiment and the p-type connecting regions 61 (refer to FIGS. 7 and 8) may be provided partially connecting, in the second parallel pn layer 81, all the p-type column regions 34 thereof that are disposed closer to the chip end than is the double-zone JTE structure 21.

A method of manufacturing the silicon carbide semiconductor device 80 according to the fourth embodiment may be implemented by suitably changing an opening pattern of an ion implantation mask for forming the p-type column regions 32, 34, in the method of manufacturing the silicon carbide semiconductor device 50 according to the first embodiment.

As described above, according to the fourth embodiment, in the second parallel pn layer, the interval between an adjacent two of the p-type column regions 34 is wider the closer the adjacent two of the p-type column regions 34 are to the chip end, whereby effects similar to those of the third embodiment may be obtained. Thus, effects of the first and second embodiments may be further obtained.

In the foregoing, the present invention is not limited to the embodiments described above and various modifications are possible within a range not departing from the spirit of the invention. For example, in a layout of the first parallel pn layer of the active region, when viewed from the front side of the semiconductor substrate, the p-type column regions may be disposed in a matrix-like pattern and the n-type column regions may be disposed in lattice-like pattern surrounding the periphery of each of the p-type column regions. Further, without limitation to a MOSFET, application is possible to a silicon carbide semiconductor device with a SJ structure having, as a drift layer, a parallel pn layer of any one of various configurations. Further, instead of the trench gate structure, a planar gate structure may be implemented in which insulated gates are provided in plate-like shape (in a plan view) on the front surface of the semiconductor substrate. In an instance of a planar gate structure, a portion of the n-type column regions of the first parallel pn layer between adjacent ones of p-type base regions constitute junction FET (JFET) regions. Further, the present invention is similarly implemented when the conductivity types (n-type, p-type) are reversed.

According to the invention described above, electric field applied to the termination region during the off-state may be evenly distributed according to the distance from the outer periphery of the active region, in the direction of the normal vector, whereby the breakdown voltage of the termination region may be enhanced. As a result, locations where avalanche breakdown occurs may be changed to the active region, which has a large area occupying a majority of the area (surface area) of the semiconductor substrate.

The silicon carbide semiconductor device according to the present invention achieves an effect in that resistance to destruction may be enhanced.

As described above, the silicon carbide semiconductor device according to the present invention is useful for power semiconductor devices used in power converting equipment, power source devices of various types of industrial machines, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A silicon carbide semiconductor device, comprising:
a semiconductor substrate that contains silicon carbide and has a first main surface and a second main surface opposite to each other, the semiconductor substrate having an active region and a termination region surrounding a periphery of the active region in a plan view of the semiconductor device;
a first parallel pn layer in which a plurality of first first-conductivity-type column regions, each being of a first conductivity type, and a plurality of first second-conductivity-type column regions, each being of a second conductivity type, are disposed adjacently and repeatedly alternate with one another, the first parallel pn layer being provided in the semiconductor substrate, in the active region;
a second parallel pn layer in which a plurality of second first-conductivity-type column regions and a plurality of second second-conductivity-type column regions are disposed adjacently and repeatedly alternate with one another, the second parallel pn layer being provided in the semiconductor substrate, in the termination region, the second parallel pn layer being in contact with the first parallel pn layer;
a device structure provided in the semiconductor substrate, between the first main surface of the semiconductor substrate and the first parallel pn layer;
a first electrode provided at the first main surface and electrically connected to the device structure; and
a second electrode provided at the second main surface of the semiconductor substrate, wherein
the plurality of second first-conductivity-type column regions and the plurality of second second-conductivity-type column regions are disposed in concentric shapes surrounding a perimeter of the first parallel pn layer in the plan view of the semiconductor device.

2. The silicon carbide semiconductor device according to claim 1, further comprising a voltage withstanding structure provided in the semiconductor substrate, between the first main surface and the second parallel pn layer, the voltage withstanding structure having:
a first second-conductivity-type region electrically connected to the first electrode, and
a second second-conductivity-type region provided adjacent to the first second-conductivity-type region, but closer to an end of the semiconductor substrate than is the first second-conductivity-type region, wherein
the second second-conductivity-type region has an impurity concentration that is lower than an impurity concentration of the first second-conductivity-type region, and
the first second-conductivity-type region and the second second-conductivity-type region are provided in concentric shapes surrounding the periphery of the active region in the plan view of the semiconductor device.

3. The silicon carbide semiconductor device according to claim 2, wherein
a border column region, which is one of the plurality of second second-conductivity-type column regions that is disposed closest to a border between the first second-conductivity-type region and the second second-conductivity-type region, satisfies
D1≥D2>D3, or
D2>D1 and D2−D1<1 μm, where
D1 is a first distance from the active region to an outer side surface of the border column region, in a direction of a normal vector from a center of the semiconductor substrate to the end of the semiconductor substrate, the outer side surface facing the end of the semiconductor substrate,
D2 is a second distance from the active region to the border between the first second-conductivity-type region and the second second-conductivity-type region, in the direction of the normal vector, and
D3 is a third distance from the active region to the border column region, in the direction of the normal vector.

4. The silicon carbide semiconductor device according to claim 2, wherein
the plurality of second second-conductivity-type column regions are electrically connected to the first electrode via the voltage withstanding structure.

5. The silicon carbide semiconductor device according to claim 2, further comprising
a second-conductivity-type connecting region selectively provided in the semiconductor substrate, between the first main surface and the second parallel pn layer, the second-conductivity-type connecting region being in contact with the voltage withstanding structure, and being closer to the end of the semiconductor substrate than is the voltage withstanding structure, the second-conductivity-type connecting region partially connecting ones of the plurality of second second-conductivity-type column regions disposed closer to the end of the semiconductor substrate than is the voltage withstanding structure.

6. The silicon carbide semiconductor device according to claim 1, wherein
the second parallel pn layer is exposed at the first main surface.

7. The silicon carbide semiconductor device according to claim 1, wherein
the plurality of second second-conductivity-type column regions are disposed in a descending order of a width thereof, in a direction from the active region to the termination region.

8. The silicon carbide semiconductor device according to claim 1, wherein
an interval between any adjacent two of the plurality of second second-conductivity-type column regions becomes wider as the interval is closer to an end of the semiconductor substrate.

9. The silicon carbide semiconductor device according to claim 2, further comprising, in the device structure:
a first semiconductor region of the second conductivity type, provided between the first main surface and the first parallel pn layer;
a plurality of second semiconductor regions of the first conductivity type, selectively provided between the first main surface and the first semiconductor region;
a plurality of trenches penetrating through the plurality of second semiconductor regions and the first semiconductor region and reaching the plurality of first first-conductivity-type column regions;
a plurality of gate electrodes provided in the plurality of trenches, via a plurality of gate insulating films, respectively; and
a plurality of second-conductivity-type high-concentration regions selectively provided between the first semiconductor region and the first parallel pn layer, closer to the second electrode than are bottoms of the plurality of trenches, the plurality of second-conductivity-type high-concentration regions having an impurity concentration that is higher than an impurity concentration of the first semiconductor region, wherein
the first electrode is electrically connected to the plurality of second semiconductor regions, the first semiconductor region, and the plurality of second-conductivity-type high-concentration regions,
the plurality of second-conductivity-type high-concentration regions extends between the first main surface and the second parallel pn layer in a direction from the active region to the termination region, the plurality of second-conductivity-type high-concentration regions being in contact with the plurality of second second-conductivity-type column regions in a depth direction of the device, and being in contact with the voltage withstanding structure in a direction of a normal vector from a center of the semiconductor substrate to the end of the semiconductor substrate, and
the plurality of second second-conductivity-type column regions is electrically connected to the first electrode, via the plurality of second-conductivity-type high-concentration regions or via the plurality of second-conductivity-type high-concentration regions and the voltage withstanding structure.

10. The silicon carbide semiconductor device according to claim 1, wherein
the plurality of first first-conductivity-type column regions and the plurality of first second-conductivity-type column regions are disposed adjacently and repeatedly alternate with one another in a first direction that is parallel to the first main surface and extend in a striped pattern in a second direction that is parallel to the first main surface and orthogonal to the first direction.
